(19) United States
(12) Patent Application Publication
(10) Pub. No.: US 2014/0118955 A1
(43) Pub. Date: May 1, 2014

(54) Display Device

(71) Applicants: Shih Hsiang Chen, Shenzhen City (CN); Gege Zhou, Shenzhen City (CN)

(72) Inventors: Shih Hsiang Chen, Shenzhen City (CN); Gege Zhou, Shenzhen City (CN)

(73) Assignee: Shenzhen China Star Optoelectronics Technology Co., Ltd., Shenzhen, Guangdong (CN)

(21) Appl. No.: 13/695,438

(22) PCT Filed: Oct. 29, 2012
(86) PCT No.: PCT/CN2012/083674

§ 371 Date: Oct. 31, 2012

(30) Foreign Application Priority Data
Oct. 25, 2012 (CN) 201210413174.1

(51) Int. Cl. H05K 5/03

(52) U.S. Cl. CPC H05K 5/03
USPC 361/728

(57) ABSTRACT

The present invention provides a display device which is configured with a front cover, a rear cover, and a display module and flexible printed circuit sandwiched between the front and rear covers, wherein the display device further includes an elastic member arranged between a bottom surface of the front cover and the flexible printed circuit. A bending or folding contour of the flexible printed circuit can be readily controlled so as to prevent the flexible printed circuit from being damaged resulted from bending and folding. In addition, the display device made in accordance with the present invention featured a lowered manufacturing cost.

### FIELD OF THE INVENTION

The present invention relates to a technical field of display, and more particularly, to a display device.

### DESCRIPTION OF PRIOR ART

A typical prior art display device generally includes a front cover, a display module, and a rear cover. The display module includes a front frame, a middle frame, and a display panel sandwiched therebetween.

In order to reduce the manufacturing cost, the front frame, the middle frame and the backframe are omitted, and have the display panel directly sandwiched between the front cover and the recover. This kind of display device is generally referred to as an integral display device.

The front cover and the rear cover are integrally formed within a mold cavity, and its dimension cannot be changed or modified after it is therefore formed. When a display module with different dimension is going to be integrally formed with the same front and rear covers, there would be a problem as a compartment within the front and rear covers for a flexible printed circuit will be changed accordingly. If the flexible printed circuit is too long to be fitted within the compartment, then the flexible printed circuit has to be folded so as to fit in the compartment. However, folding the flexible printed circuit repeatedly or in a wanted way will easily damage the flexible printed circuit causing the malfunctions of the signals. If the flexible printed circuit is damaged, then the display device is also malfunctioned.

In conclusion, there is a necessity to provide a display device to resolve the above-described issue.

### SUMMARY OF THE INVENTION

It is the objective of the present invention to provide a display device in which a flexible printed circuit can be readily fitted therein without folding or bending so as to prevent the flexible printed circuit from being damaged resulted from bending and folding. In addition, the display device made in accordance with the present invention featured a lowered manufacturing cost.

In order to resolve the issue encountered by the prior art, the present invention provides a technical solution by introducing a display device which is configured with a front cover, a rear cover, and a display module and flexible printed circuit sandwiched between the front and rear covers, wherein the display device further includes an elastic member arranged between a bottom surface of the front cover and the flexible printed circuit, wherein the elastic member has one end anchored onto the bottom surface of the front cover, and the other end abuts against to the flexible printed circuit, wherein the elastic member is a soft foam or spring member.

Wherein the elastic member includes a plurality of elastic units evenly arranged across the bottom surface of the front cover, each of the elastic units has the same height.

Wherein the elastic member includes a plurality of elastic units evenly arranged across the bottom surface of the front cover, each of the elastic units has different height.

In order to resolve the issue encountered by the prior art, the present invention provides a technical solution by introducing a display device which is configured with a front cover, a rear cover, and a display module and flexible printed circuit sandwiched between the front and rear covers, wherein the display device further includes an elastic member arranged between a bottom surface of the front cover and the flexible printed circuit.

Wherein the elastic member has one end anchored onto the bottom surface of the front cover, and the other end abuts against to the flexible printed circuit.

Wherein the elastic member includes a plurality of elastic units evenly arranged across the bottom surface of the front cover, each of the elastic units has the same height.

Wherein the elastic member includes a plurality of elastic units evenly arranged across the bottom surface of the trout cover, each of the elastic units has different height.

Wherein the plurality elastic units are arranged in steps.

Wherein the elastic units reduce its height along a direction toward the display module.

Wherein the elastic units increase its height along a direction toward the display module.

Wherein the elastic members includes a first elastic unit, a second elastic unit, and a third elastic unit, wherein the height of the first and third elastic units are same, while the height of the second elastic unit is substantially smaller than the first or the third elastic units.

Wherein the elastic members includes a first elastic unit, a second elastic unit, and a third elastic unit, wherein the height of the first and third elastic units are same, while the height of the second elastic unit is substantially larger than the first or the third elastic units.

Wherein the elastic member is a soft foam or spring member.

The present invention can be concluded with the following advantages. As compared to the existing prior art, an elastic member is incorporated, within the display device integrally formed and in which the elastic member is in constant contact with the flexible printed circuit so as to readily and properly control the folding contour of the flexible printed circuit such that the flexible printed circuit will not be damaged resulted from repeatedly bending or folding. In addition, the manufacturing cost is comparably low.

### BRIEF DESCRIPTION OF DRAWINGS

FIG. 1 is an illustrational and structural view of a display device made in accordance with a first embodiment of the present invention;

FIG. 2 is an illustrational and structural view of a display device made in accordance with a second embodiment of the present invention;

FIG. 3 is a partial and structural view of a display device made in accordance with a third embodiment of the present invention;

FIG. 4 is a partial and structural view of a display device made in accordance with a fourth embodiment of the present invention;

FIG. 5 is a partial and structural view of a display device made in accordance with a fifth embodiment or the present invention;

FIG. 6 is a partial and structural view of a display device made in accordance with a sixth embodiment of the present invention; and

FIG. 7 is a partial and structural view of a display device made in accordance with a seven embodiment of the present invention.

### DETAILED DESCRIPTION OF PREFERRED EMBODIMENT

Detailed description will be given along with the embodiments illustrated in the attached drawings.

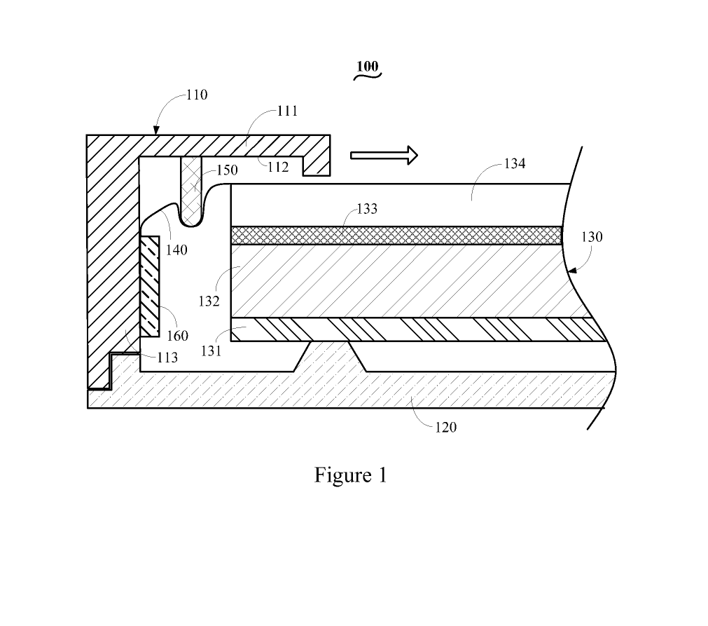

FIG. 1 is an illustrational and structural view of a display device made in accordance with a first embodiment of the present invention. As shown, the display device 100 includes a front cover 110, a rear cover 120, a display module 130, a flexible printed circuit 140, and an elastic member 150.

The display module 130 is a typical liquid crystal display module with side-entrance. The display module 130 includes a reflector 131, a waveguide 132, an optical film 133, and a display panel 134 arranged in sequential. The display module 130 is attached to the rear cover 120, and then the front cover 110 is assembled with the rear cover 120.

The flexible printed circuit 140 is used to interconnect the display panel 134 and a printed circuit board 160 located on a side 113 of the front cover 110.

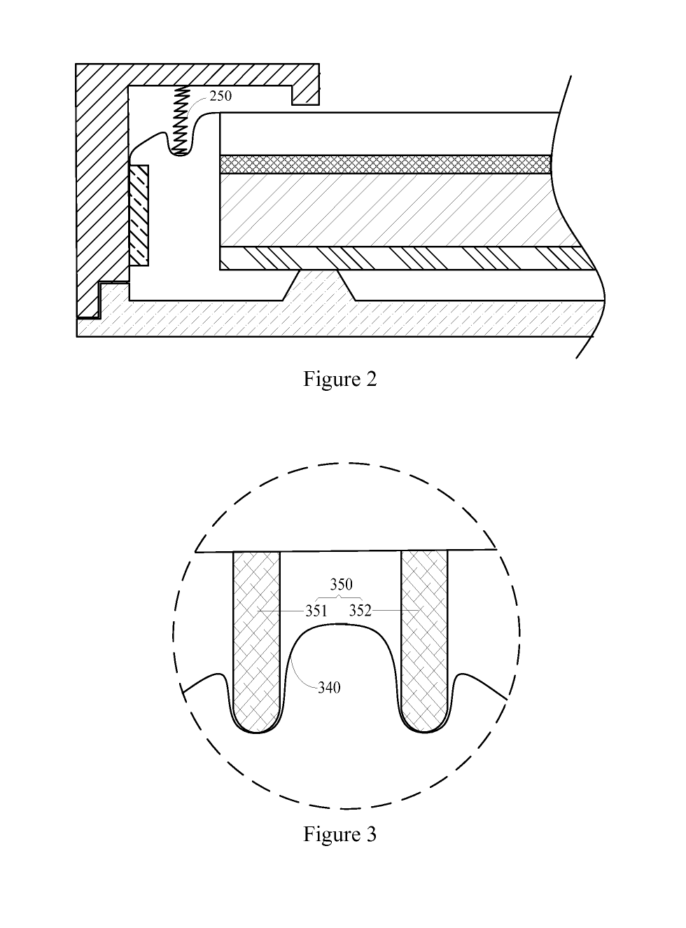

The elastic member 150 is arranged on a bottom surface 112 of a top 111 of the front cover 110. An end of the elastic member 150 is anchored onto the bottom surface 112, and the other end abuts against to the flexible printed circuit 140. Wherein the elastic member 150 can be made from soft foam. In other alternative, as shown in FIG. 2, the elastic member 150 can be embodied as a spring 250, or any other suitable and elastic material fitted to the requirements.

In the current embodiment, the elastic member 150 abuts against the flexible printed circuit 140. Since the elastic member 150 can readily contrast or expand in view of the workload applied thereto, as a result, the elastic member 150 can readily control the contour of the flexible printed circuit 140.

It should be noted that even the display module 130 is illustrated as the liquid crystal display module with side-entrance, however, the elastic member 150 should not be limited only to the liquid crystal display device. It can be used to any liquid crystal display as long as flexible printed circuit is used.

The working principle of the elastic member will be detailedly disclosed in view of the following embodiments. On the other hand, the arrangement and installation of the elastic members will also be illustrated.

FIG. 3 is a partial and structural view of a display device made in accordance with a third embodiment of the present invention. Referring to FIG. 3, as compared to FIGS. 1 and 2, the difference between the embodiments is that the elastic member 350 includes a first elastic unit 351, and a second elastic unit 352. The first and second elastic units 351 and 352 are arranged on the bottom surface of the front cover and the first and second elastic units 351, 352 have the same height.

In the current embodiment, the elastic member 350 can readily control the bending contour of the flexible printed circuit 340 when a distance or gap between the front cover and the display module is too big for accommodate by the flexible printed circuit. As a result, the flexible printed circuit will not suffer from damaging resulted from extensively bending or folding. Any interruption of signal transmission will therefore be avoided.

It should be noted that in other embodiments, the quantity of the elastic member 350 can be readily increased or reduced according to the requirements. It should not be limited to only two as illustrated in drawings.

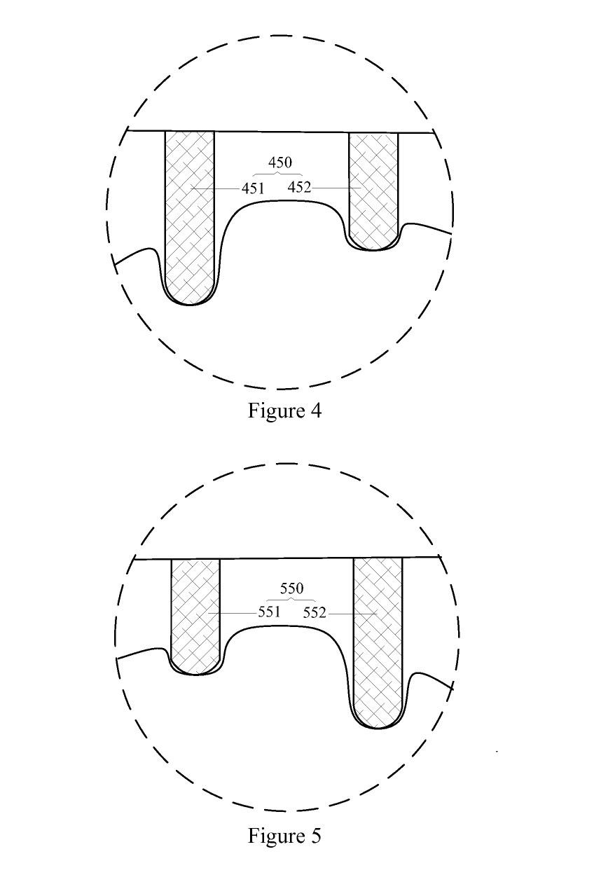

FIG. 4 is a partial and structural view of a display device made in accordance with a fourth embodiment of the present invention. Referring to FIG. 4, the difference with the embodiment in FIG. 3 is that the height of the first elastic unit 451 and a second elastic unit 452 of the elastic member 450 are different from each other, i.e. the height of the first elastic unit 451, and the second elastic unit 452 decreases along a direction extending along the display module (a direction marked with arrow in FIG. 1). Accordingly, a step-like arrangement is shown.

It can be readily understood in view of the embodiment illustrated in FIG. 4, in the fifth embodiment shown in FIG. 5, a height of the first elastic unit 551 and the second elastic unit 552 of the elastic member 550 are different from each other, i.e. the height of the first elastic unit 551, and the second elastic unit 552 increases along a direction extending, along the display module (a direction marked with arrow in FIG. 1). Accordingly, a step-like arrangement is shown.

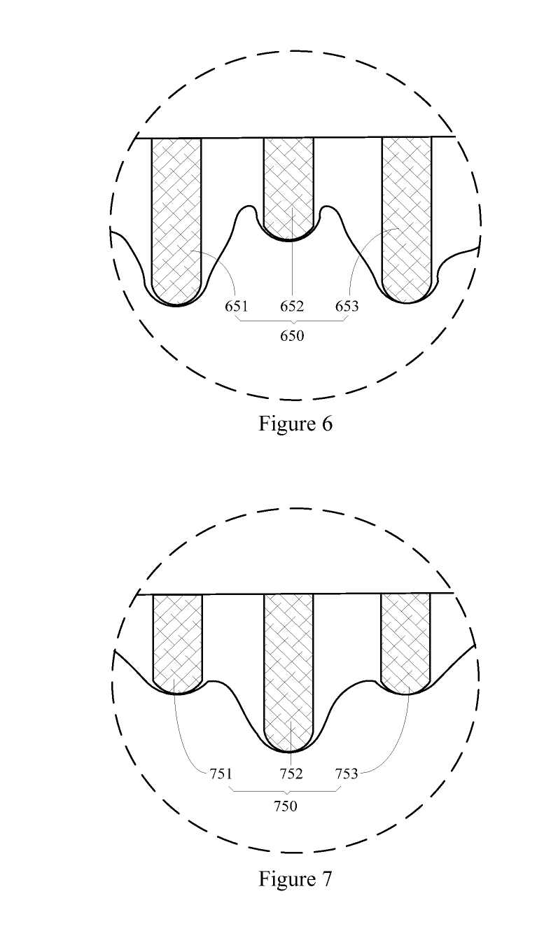

Referring to FIG. 6 which is a partial and structural view of a display device made in accordance with a sixth embodiment of the present invention. In the current embodiment, the elastic member 650 includes a first elastic unit 651, a second elastic unit 652, and a third elastic unit 653 arranged spaced from each other in line.

In this embodiment, the first elastic unit 651 and the third elastic unit 653 have the same height, while the second elastic unit 652 has a height lower than the first or the second elastic units 651, 653.

Referring to FIG. 7 which is a partial and structural view of a display device made in accordance with a seven embodiment of the present invention. In the current embodiment, the elastic member 750 includes a first elastic unit 751, a second elastic unit 752, and a third elastic unit 753 arranged spaced front each other in line.

In this embodiment, the first elastic unit 751 and the third elastic unit 753 have the same height, while the second elastic unit 752 has a height higher than the first or the second elastic units 751, 753.

The working principle of the embodiments shown in FIGS. 4, 5, 6 and 7 are similar to what disclosed above, as a result, no detailed description is given herebelow.

In conclusion, an elastic member is incorporated within the display device integrally formed and in which the elastic member is in constant contact with the flexible printed circuit so as to readily and properly control the folding contour of the flexible printed circuit such that the flexible printed circuit will not be damaged resulted from repeatedly bending or folding. In addition, the manufacturing cost is comparably low.

Apparently, with the spirit of the embodiments disclosed, person in the skilled in the art can readily come out with other modifications as well as improvements without undue experiments to adjust the positions and installations of the elastic members as long as an end of the elastic member is anchored onto the bottom surface of the front cover, and the other end abuts against the flexible printed circuit. As a result, the bending and folding contour of the flexible printed circuit can be readily controlled so as to avoid damaging. By this, the risk of breaking conductors within the flexible printed circuit can be effectively avoided. Furthermore, the embodiments will not merely limited to FIGS. 1 to 7.

The above described is merely a primary disclosure. In order to readily clarify the technical solution, and therefore implement that technical solution in view of the specification, a detailed description in view of a preferable embodiment in conjunction with accompanied drawings will be given herebelow. By this, other purposes, features and characteristics can be readily appreciated through the detailed description.

1. A display device which is configured with a front cover, a rear cover, and a display module and flexible printed circuit sandwiched between the front and rear covers, wherein
the display device further includes an elastic member arranged between a bottom surface of the front cover and the flexible printed circuit, wherein the elastic member has one end anchored onto the bottom surface of the front cover, and the other end abuts against to the flexible printed circuit, wherein the elastic member is a soft foam or spring member.

2. The display device as recited in claim 1, wherein the elastic member includes a plurality of elastic units evenly arranged across the bottom surface of the front cover, each of the elastic units has the same height.

3. The display device as recited in claim 1, wherein the elastic member includes a plurality of elastic units evenly arranged across the bottom surface of the front cover, each of the elastic units has different height.

4. A display device which is configured with a front cover, a rear cover, and a display module and flexible printed circuit sandwiched between the front and rear covers, wherein
the display device further includes an elastic member arranged between a bottom surface of the front cover and the flexible printed circuit.

5. The display device as recited in claim 4, wherein the elastic member has one end anchored onto the bottom surface of the front cover, and the other end abuts against to the flexible printed circuit.

6. The display device as recited in claim 5, wherein the elastic member includes a plurality of elastic units evenly arranged across the bottom surface of the front cover, each or the elastic units has the same height.

7. The display device as recited in claim 5, wherein the elastic member includes a plurality of elastic units evenly arranged across the bottom surface of the front cover, each of the elastic units has different height.

8. The display device as recited in claim 7, wherein the plurality elastic units are arranged in steps.

9. The display device as recited in claim 8, wherein the elastic units reduce its height along a direction toward the display module.

10. The display device as recited in claim 8, wherein the elastic units increase its height along a direction toward the display module.

11. The display device as recited in claim 7, wherein the elastic members includes a first elastic unit, a second elastic unit, and a third elastic unit, wherein the height of the first and third elastic units are same, while the height of the second elastic unit is substantially smaller than the first or the third elastic units.

12. The display device as recited in claim 7, wherein the elastic members includes a first elastic unit, a second elastic unit, and a third elastic unit, wherein the height of the first and third elastic units are same, while the height of the second elastic unit is substantially larger than the first or the third elastic units.

13. The display device as recited in claim 4, wherein the elastic member is a soft foam or spring member.
